(19) United States
(12) Patent Application Publication
(10) Pub. No.: US 2017/0280592 A1
(43) Pub. Date: Sep. 28, 2017

(54) COMPUTER HOUSING HEAT DISSIPATING CONFIGURATION

(71) Applicant: IN WIN DEVELOPMENT, INC., Taoyuan Hsien (TW)

(72) Inventor: WEN-HSIEN LAI, Taoyuan Hsien (TW)

(73) Assignee: IN WIN DEVELOPMENT, INC., Taoyuan Hsien (TW)

(21) Appl. No.: 15/080,409

(22) Filed: Mar. 24, 2016

(51) Int. Cl. H05K 7/20

(52) U.S. Cl. CPC H05K 7/20736

(57) ABSTRACT

The present invention is a new computer housing heat dissipating configuration provided with both a heat dissipation function and the function to hide the upper power source. The upper portion of the computer housing is also installed with one to three fans that blow toward the corresponding ventilation holes in the side panel. A fan is further installed in the rear portion of the computer housing. The aforementioned fans all expel heat outwardly from the computer system, thereby causing the lower portion of the computer housing to form negative air pressure that draws air upwards from the bottom portion, whereupon the fans expel the high temperature air flow to the outside air of the computer, thus achieving premium heat dissipation.

### BACKGROUND OF THE INVENTION

(a) Field of the Invention

The present invention relates to heat dissipation within a computer housing unit. It provides premium thermal solutions, while concealing the power source near the upper region of the chassis.

(b) Description of the Prior Art

Under normal operation, the internal components of the-computer will produce a large amount of heat energy. In order to prevent the heat from accumulating, which would seriously affect the electronic components from operating normally, heat dissipating devices are used to maintain the internal temperature of the computer at a definite predetermined operating temperature. However, most computer chassis on the market only come with one or a few fans to blow away the high temperature air flow to assist in removing or expelling the heat. Nevertheless, those fans are unable to effectively expel the heat to the outside air. After the system has been operating for a period of time, the internal air will have gradually risen, affecting the efficiency and stability of the computer system. Hence, there is a need for improvement in heat dissipation.

### SUMMARY OF THE INVENTION

Accordingly, the primary objective of the present invention lies in providing a bottom panel and one of the side panels of a computer chassis with ventilation holes. In addition, a partition panel is used to form an air passage in the upper portion of the computer housing; moreover, the partition panel also provides the function of hiding the power supply and its wires to give the computer case a more aesthetic appeal. Furthermore, heat removal fans are positioned to face outward in the upper and rear portion of the computer housing, thereby enabling the lower portion of the computer chassis to form negative air pressure that draws air upwards from the bottom panel. The hot air inside the computer enclosure is then expelled outwards, thus strengthening the thermal solutions.

Detailed drawings and descriptions are provided below to fully explain the above technological methods of the invention.

### BRIEF DESCRIPTION OF THE DRAWINGS

FIG. 1 shows a schematic view of the present invention.

FIG. 2 shows an internal structural view of the present invention.

FIG. 3 shows another internal structural view of the present invention.

FIG. 4 shows another schematic view of the present invention.

### DETAILED DESCRIPTION OF THE PREFERRED EMBODIMENTS

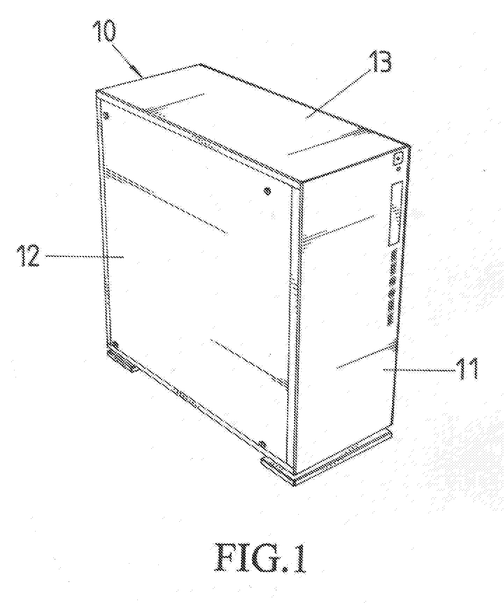

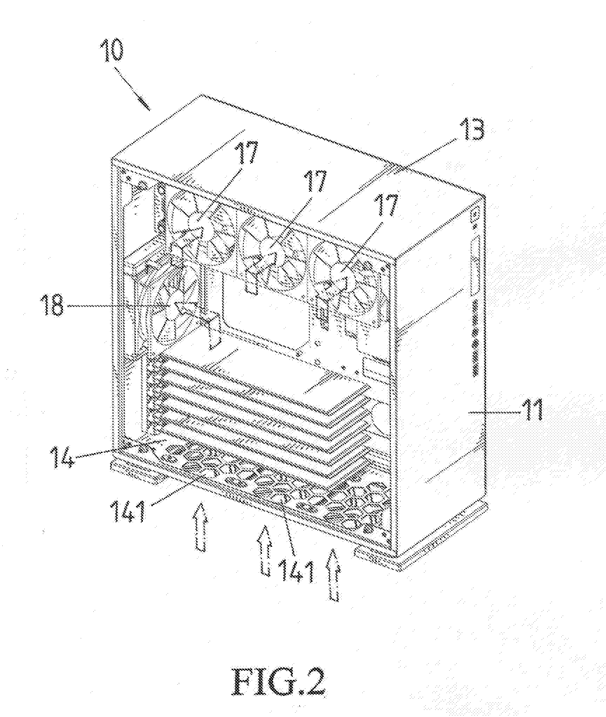

Referring to FIG. 1, which shows a schematic view of an embodiment of the present invention, wherein, a complete computer case is constructed after installing front panel 11, left panel 12, and top panel 13 to computer housing 10. Referring to FIG. 2, which shows a structural view of the interior of the computer housing 10 after detaching the left panel 12, and the drawing clearing shows heat dissipating devices in the interior of the computer housing 10. Moreover, bottom panel 14 of the computer housing 10 is provided with net-like ventilation holes 141.

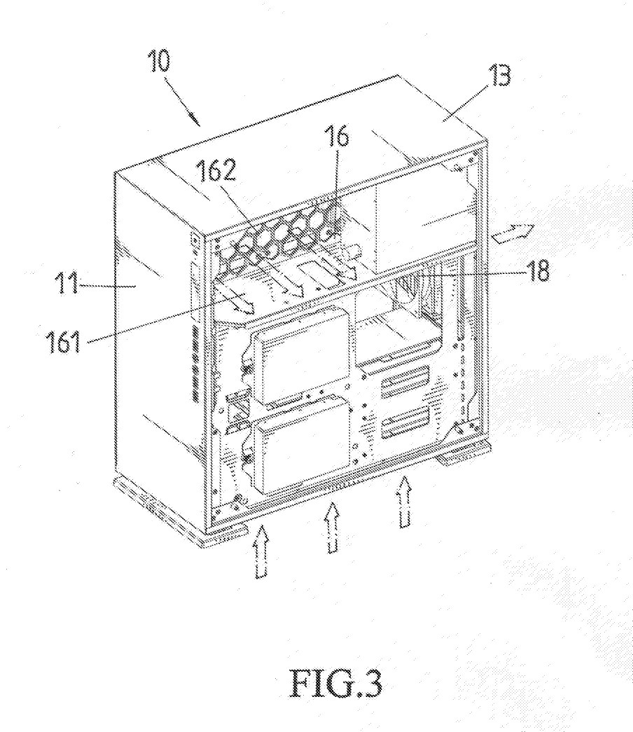

Referring to FIG. 3, partition panel 16 is used to form an air passage 161 in the upper portion of computer housing 10, and partition panel 16 is provided with ventilation holes 162. Partition panel 16 also provides the function of concealing the upper power source (such as a power supply) to give computer housing 10 a more aesthetic appeal.

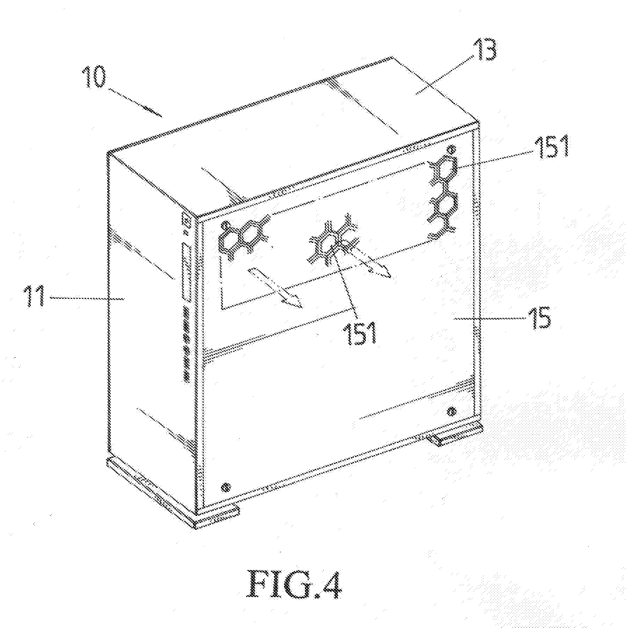

Referring to FIG. 4, right panel 15 of the computer housing 10 is provided with net-like ventilation holes 151. As shown in FIG. 2, the upper portion of the computer housing 10 is also provided with one to three fans 17 that blows toward the corresponding ventilation holes 151 in the right panel 15. For practical purposes, the embodiment disclosed in the present invention is preferably provided with three of the heat dissipating fans 17. The rear portion of the computer housing 10 is also provided with fan 18. The fan 18 is a special purpose fan for the power supply unit (PSU) of the computer case, and faces in the direction of the computer system to strengthen cooling solutions. The aforementioned fans 17, 18 all expel heat outwardly from the computer system, thereby causing the lower portion of the computer housing 10 to form a negative air pressure that draws air upwards from the bottom portion, whereupon the fans 17, 18 expel the high temperature air flow to the outside through the ventilation holes 151 of the right panel 15 of the computer housing 10 (as shown in FIG. 4), thus providing optimal heat dissipation.

In conclusion, according to the above description of the embodiment of the present invention, the new computer housing heat dissipating configuration of the present invention is able to effectively improve the cooling presence of said enclosure.

It is of course to be understood that the embodiments described herein are merely illustrative of the principles of the invention, and that a wide variety of modifications may be affected pending on the person's skill level.

What is claimed is:

1. A computer housing heat dissipating configuration, wherein a computer housing provided with ventilation holes on the bottom and on one of the side panels, there is the partition panel with ventilation holes in the upper portion of the computer hosing, at least one fan on partition panel and one on the rear is necessary during installation, the fans all expel heat outwards, thereby causing the lower portion of the computer housing to form a negative air pressure that draws air upwards from the ventilation holes in the bottom portion, whereupon the fans in the upper portion expels the high temperature air flow to the outside of the computer.

2. The computer housing heat dissipating configuration according to claim 1, wherein it will be preferred to installed all three fans on the top partition panel.
